(19) United States
(12) Patent Application Publication
(10) Pub. No.: US 2025/0062284 A1
(43) Pub. Date: Feb. 20, 2025

(54) THIN WAFER, METHOD OF MANUFACTURING THE THIN WAFER, STACK TYPE SEMICONDUCTOR DEVICE INCLUDING THE THIN WAFER AND METHOD OF MANUFACTURING THE STACK TYPE SEMICONDUCTOR DEVICE

(71) Applicant: SK hynix Inc., Icheon-si (KR)

(72) Inventor: Hee Sun LEE, Icheon-si (KR)

(21) Appl. No.: 18/434,610

(22) Filed: Feb. 6, 2024

(30) Foreign Application Priority Data
Aug. 16, 2023 (KR) 10-2023-0106941

(51) Int. Cl. H01L 25/065; H01L 21/306; H01L 21/762; H01L 23/00

(52) U.S. Cl. CPC H01L 25/0657; H01L 21/30625; H01L 21/76224; H01L 24/08; H01L 24/80; H01L 2224/08145; H01L 2224/80895; H01L 2224/80896

(57) ABSTRACT

In an embodiment, a wafer may include a substrate including a first surface and a second surface opposite to each other, a polishing stop layer formed in a selected portion of the substrate, the polishing stop layer including one or more insulation trenches each filled with an insulation material and having a depth corresponding to a thickness of the substrate, and a device layer supported by the substrate and structured to include a plurality of conductive patterns configured to electrically connect different circuit elements in the substrate.

### PRIORITY CLAIM AND CROSS-REFERENCES TO RELATED APPLICATION

This patent document claims the priority and benefits of Korean application number 10-2023-0106941, filed on Aug. 16, 2023, which is incorporated herein by reference in its entirety as part of the disclosure of this patent document.

### TECHNICAL FIELD

Various embodiments generally relate to a semiconductor technology.

### BACKGROUND

A stack-type semiconductor device may include at least two wafers (or at least two semiconductor dies) that are vertically stacked.

To reduce the size of the stack-type semiconductor device and the signal transmission path in the stack-type semiconductor device, a thinning process may be performed on the wafers (or the semiconductor dies).

The thinning process may include bonding the wafers to each other, and to this end, a polishing a backside of at least one of the wafers is polished.

Therefore, such a polishing operation is one of the most important operations that are performed to form the stack-type semiconductor device.

### SUMMARY

The disclosed technology can be implemented in some embodiments to provide a thin wafer having a uniform thickness.

The disclosed technology can be implemented in some embodiments to provide a method of manufacturing the above-mentioned thin wafer.

The disclosed technology can be implemented in some embodiments to provide a stack type semiconductor device including the above-mentioned thin wafer.

The disclosed technology can be implemented in some embodiments to provide a method of manufacturing the above-mentioned stack type semiconductor device.

In some embodiments, a wafer may include a substrate including a first surface and a second surface opposite to each other, a polishing stop layer formed in a selected portion of the substrate, the polishing stop layer including one or more insulation trenches each filled with an insulation material and having a depth corresponding to a thickness of the substrate, and a device layer supported by the substrate and structured to include a plurality of conductive patterns configured to electrically connect different circuit elements in the substrate.

In some embodiments, a method of manufacturing a wafer may include forming a semiconductor substrate including a front surface and a bottom surface spaced apart from the front surface by a first thickness, forming, in the semiconductor substrate, a polishing stop layer from the front surface of the semiconductor substrate, the polishing stop layer having a first depth that is smaller than the first thickness, forming an isolation layer in the semiconductor substrate that includes the polishing stop layer formed in the semiconductor substrate, the isolation layer having a second depth that is smaller than the first depth, forming a device layer over the front surface of the semiconductor substrate that includes the polishing stop layer and the isolation layer formed in the semiconductor substrate, and polishing the bottom surface of the semiconductor substrate until the polishing stop layer is exposed.

In some embodiments, a method of manufacturing a stack type semiconductor device may include forming a first wafer by forming a first device layer and a first bonding layer over a first substrate that includes a plurality of polishing stop layers, forming a second wafer by forming a second device layer and a second bonding layer over a second substrate, stacking the first wafer on the second wafer such that the first bonding layer faces the second bonding layer and a bottom surface of the first substrate is exposed, performing a hybrid-bonding to attach the first bonding layer of the first wafer to the second bonding layer of the second wafer, and polishing the exposed bottom surface of the first wafer until the polishing stop layers are exposed, wherein the polishing stop layers comprise an insulation trench having a depth that is smaller than a thickness of the first substrate.

In example embodiments, a thin wafer may include a thin substrate, a device layer and a polishing stop layer. The thin substrate may have a first surface and a second surface opposite to each other. The device layer may be formed on the first surface of the thin substrate. The device layer may include a plurality of conductive patterns. The polishing stop layer is formed at a selected portion of the thin substrate. The polishing stop layer may include an insulation trench having a depth corresponding to a thickness of the thin substrate.

In example embodiments, the thin wafer may further include a plurality of conductive structures. The conductive structures may be formed through the thin substrate. The conductive structures may be electrically connected to an electrode of the device layer.

In example embodiments, the polishing stop layer may be positioned between the adjacent conductive structures.

In example embodiments, the thin substrate may include a plurality of die regions and a scribe lane for defining the die regions. The selected portion may be at least one of the die regions and the scribe lane.

In example embodiments, the thin substrate may include a pattern concentration region and a dummy region. The selected portion may be at least one of the pattern concentration region and the dummy region.

In example embodiments, the polishing stop layer may be arranged symmetrically with each other on a whole surface of the thin substrate.

In example embodiments, a method of manufacturing a thin wafer may include providing a semiconductor substrate. The semiconductor substrate may have a front surface and a bottom surface spaced apart from each other by a first thickness. A polishing stop layer is formed from the front surface of the semiconductor substrate. The polishing stop layer may have a first depth less than the first thickness. An isolation layer may be formed at the semiconductor substrate with the polishing stop layer. The isolation layer may have a second depth shallower than the first depth. A device layer may be formed on the front surface of the semiconductor substrate with the polishing stop layer and the isolation layer. The bottom surface of the semiconductor substrate may be polished until the polishing stop layer may be exposed to form the thin wafer.

In example embodiments, the first depth may be about 0.1% to about 2% of the first thickness.

In example embodiments, there may be provided a method of manufacturing a stack type semiconductor device. In the method of manufacturing the stack type semiconductor device, a first device layer and a first bonding layer may be sequentially formed on a first substrate with a plurality of polishing stop layers to provide a first wafer. A second device layer and a second bonding layer may be sequentially formed on a second substrate to provide a second wafer. The first wafer may be stacked on the second wafer to face the first bonding layer and the second bonding layer to each other, thereby exposing a bottom surface of the first substrate. The first bonding layer of the first wafer and the second bonding layer of the second wafer may be hybrid-bonded to each other. The bottom surface of the first substrate may be polished until the polishing stop layers may be exposed to form a thin substrate. The polishing stop layers may include a trench including an insulation material. The trench may have a depth less than a thickness of the first substrate.

According to example embodiments, there may be provided a stack type semiconductor device. The stack type semiconductor device may include a first wafer and a second wafer. The first wafer may include a first substrate and a first bonding layer on the first substrate. The second wafer may include a second substrate and a second bonding layer on the second substrate. The second bonding layer may be hybrid-bonded to the first bonding layer. The first substrate may include a plurality of first polishing stop layers. The first polishing stop layer may have an insulation trench structure having a depth corresponding to a thickness of the first substrate.

Therefore, in some example embodiments, the polishing stop layer having the insulation trench structure may be formed in the semiconductor substrate. The polishing stop layer may be arranged symmetrically with each other on the whole surface of the semiconductor substrate. Alternatively, the polishing stop layer may be arranged in a region having a rapid polishing speed, a region with a low pattern density, or the adjacent conductive structures to improve polishing uniformity. Thus, the improvement of the polishing uniformity may provide the thin substrate having a uniform thickness without a damage of conductive members in the semiconductor substrate, the thin wafer and the stack type semiconductor device including the thin substrate.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a cross-sectional view illustrating a thin wafer based on example embodiments;

FIG. 2A is a plan view illustrating a thin wafer based on example embodiments;

FIG. 2B is an enlarged plan view illustrating a portion “A” in FIG. 2A;

FIGS. 3A and 3B are plan views illustrating a polishing stop layer based on example embodiments;

FIG. 4 is a cross-sectional view taken along a line IV-IV′ in FIG. 3A;

FIGS. 5 to 8 are cross-sectional views illustrating a method of manufacturing a thin wafer based on example embodiments;

FIGS. 9 to 11 are cross-sectional views illustrating a method of manufacturing a stack type semiconductor device based on example embodiments; and

FIG. 12 is a cross-sectional view illustrating a stack type semiconductor device based on example embodiments.

### DETAILED DESCRIPTION

Features of the technology disclosed in this patent document are described by examples with reference to the accompanying drawings. Although a few embodiments of the disclosed technology will be discussed, the disclosed technology can be implemented in various ways beyond the specifics of the examples described herein.

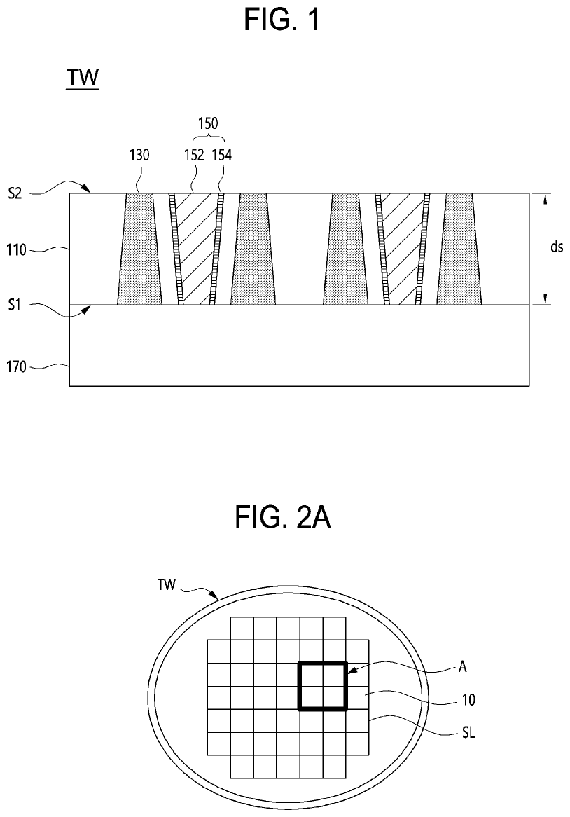

FIG. 1 is a cross-sectional view illustrating a thin wafer based on example embodiments.

Referring to FIG. 1, a thin wafer TW of example embodiments may include a thin substrate 110 and a device layer 170. In some implementations, The thin substrate 110 may include a bulk wafer or a bulk substrate (or part of the bulk wafer or part of the bulk substrate), which is a semiconductor material wafer that can be used for the fabrication of integrated circuits. In some implementations, the thin substrate 110, the thin wafer TW including the thin substrate 110, and a “wafer” may be a resultant device or structure on which at least one of a front end of line (FEOL) process and a back end of line (BEOL) process is performed.

The thin substrate 110 may include one or more semiconductor materials, and the thin substrate 110 can be used for the fabrication of integrated circuits. For example, the thin substrate 110 may include silicon, silicon germanium, doped or undoped polysilicon, doped or undoped silicon wafers, patterned or non-patterned wafers, doped silicon, germanium, gallium, arsenic and a combination of two or more of the materials listed above. In example embodiments, the semiconductor material may include silicon.

In example embodiments, the thin substrate 110 may include a semiconductor material such as silicon, carbon, germanium, silicon germanium, germanium tin, a combination thereof, etc. The thin substrate 110 may include at least one of silicon, germanium, gallium, arsenic and phosphorus.

The thin substrate 110 may include a first surface S1 and a second surface S2 opposite to each other. The first surface S1 and the second surface S2 may be spaced apart from each other by a thickness ds of the thin substrate 110. The thickness ds of the thin substrate 110 may be thinner than a thickness of the bulk wafer. In example embodiments, the thickness of the thin substrate 110 may be about 0.8 μm to about 16 μm.

The thin substrate 110 may include at least one polishing stopper or polishing stop layer 130. In some implementations, the term “polishing stop layer” may be used to indicate a layer that is used to slow or stop a chemical mechanical polish process. The polishing stop layer 130 may have a trench structure having a depth corresponding to the thickness ds of the thin substrate 110. Thus, the polishing stop layer 130 may have a structure formed in the thin substrate 110. The polishing stop layer 130 having the depth ds may have various shapes.

The polishing stop layer 130 may be an insulation trench that is filled with an insulation material. For example, the insulation material may include silicon oxide, silicon nitride, an organic insulation material, etc.

The polishing stop layer 130 may be arranged in selected portions of the thin substrate 110.

In example embodiments, the polishing stop layer 130 may be symmetrically positioned at regions in the thin substrate 110. The polishing stop layer 130 may be uniformly arranged in the selected portions of the thin substrate 110.

Further, the number of the polishing stop layers 130 in a region of the thin wafer having a rapid polishing speed may be greater than the number of the polishing stop layers 130 in a region of the thin wafer having a slow polishing speed.

Therefore, the bulk wafer may be planarized by performing a polishing operation using the polishing stop layers 130 having the insulating trench structure to slow or stop the polishing operation, thereby forming the thin substrate 110 having the planarized second surface S2.

The thin substrate 110 based on example embodiments may further include a conductive structure 150 in the thin substrate 110. The conductive structure 150 may be formed in the thin substrate 110.

The conductive structure 150 may include a conductive via 152 and a sidewall insulation layer 154. The conductive via 152 may include a conductive material.

The conductive via 152 may be coupled between an electrical component on the first surface S1 of the thin substrate 110 and an electrical component on the second surface S2 of the thin substrate 110.

The sidewall insulation layer 154 may be interposed between the conductive via 152 and the thin substrate 110 to electrically isolate the conductive via 152 from the thin substrate 110.

For example, the conductive structure 150 may have a height that is similar or substantially identical to the thickness ds of the thin substrate 110.

The thin wafer TW based on example embodiments may further include a device layer 170. For example, the device layer 170 may be formed on the first surface S1 of the thin substrate 110.

The device layer 170 may include at least one electrode and interconnection layers (or interconnects).

For example, the device layer 170 may include an active element and/or a passive element.

Further, the device layer 170 may include at least one of transistors, memories, capacitors, inductors, resistors, switches, integrated circuits, amplifiers, photoelectron elements and other electronic elements, and multi-interconnection layers connected between thereof.

Alternatively, the device layer 170 may include at least one of a memory component having a plurality of memory cells and a logic/drive component for driving the memory component. The memory component may include a plurality of the memory cells arranged in a two-dimension or a three-dimension.

An electrode of the element, or the interconnection layer connected to the electrode in the device layer 170 may be electrically connected with the conductive structure 150 exposed through the first surface S1.

Although not depicted in drawings, an external terminal or a bonding pad may be formed on the conductive structure 150 exposed through the second surface S2 of the thin substrate 110.

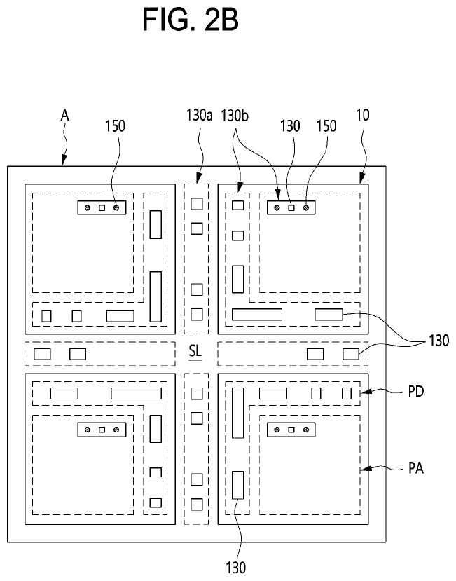

FIG. 2A is a plan view illustrating a thin wafer based on example embodiments and FIG. 2B is an enlarged plan view illustrating a portion “A” in FIG. 2A.

Referring to FIGS. 2A and 2B, the thin wafer TW may include a substrate with a plurality of dies 10. The dies 10 may be divided by a scribe lane SL on the substrate. FIGS. 2A and 2B may show an upper surface of the thin wafer TW on which the device layer 170 in FIG. 1 may be formed. The device layer 170 may not be shown in FIGS. 2A and 2B. Further, the substrate may correspond to the thin substrate 110 in FIG. 1.

The device layer on the die 10 may include the active element, the passive element, the interconnection layers, the memory component and the logic/drive component. The device layer on the scribe lane SL may include a test pattern and an alignment key.

For example, the scribe lane SL may include a polishing stop layer region 130b that includes at least one the polishing stopper layer 130. Further, the die 10 may include at least one polishing stop layer region 130b that includes at least one the polishing stop layer 130. The polishing stop layers 130 in the polishing stop layer regions 130a and 130b may include various shapes.

In example embodiments, the polishing stop layers 130 in the polishing stop layer region 130a may have various shapes and may be spaced apart from each other by a gap. The polishing stop layer 130 in the polishing stop layer region 130a may overlap with at least one of the test patterns and the alignment key formed at the scribe lane SL. Alternatively, the polishing stop layer 130 in the polishing stop layer region 130a may be arranged between the test patterns and the alignment key which are arranged at the scribe lane SL.

The polishing stop layer region 130b of the die 10 may be positioned in at least one of a pattern concentration region PA and a dummy region PD. For example, the pattern concentration region PA is a region of the die 10 where a plurality of circuit patterns are distributed and a density of the plurality of circuit patterns in the pattern concentration region PA is higher than a set density. The dummy region PD is a region of the die 10 where a plurality of circuit patterns are distributed and a density of the plurality of circuit patterns is lower than the set density.

For example, the pattern concentration region PA may be part of the substrate corresponding to a region where the circuit patterns are densely distributed (e.g., memory cell array). The dummy region PD may be part of the substrate corresponding to a region where the circuit patterns are coarsely distributed (e.g., logic circuit region or peripheral circuit region).

A relatively large number of conductive structures 150 may be integrated in the die 10 corresponding to the pattern concentration region PA, e.g., in the thin substrate. A relatively small number of the conductive structure 150 may be integrated in the die 10 corresponding to the dummy region PD, e.g., in the thin substrate.

In example embodiments, the polishing stop layers 130 in the polishing stop layer region 130b may not be in contact with the conductive structure 150 in the polishing stop layer region 130b.

Alternatively, the polishing stop layer region 130b may be positioned in the dummy region PD. The polishing stop layers 130 may be uniformly distributed in the polishing stop layer region 130b.

Further, the polishing stop layer region 130b may be positioned in the pattern concentration region PA. The polishing stop layers 130 in the patterns concentration region PA may have a size smaller than a size of the polishing stop layers 130 in the dummy region PD and the scribe lane SL.

At least one of the polishing stop layers 130 in the polishing stop layer regions 130a and 130b may be positioned between the adjacent conductive structures 150. In some implementations, the polishing stop layer 130 in the pattern concentration region PA may be positioned between the adjacent conductive structures 150 to cut off a signal interference between the conductive structures 150.

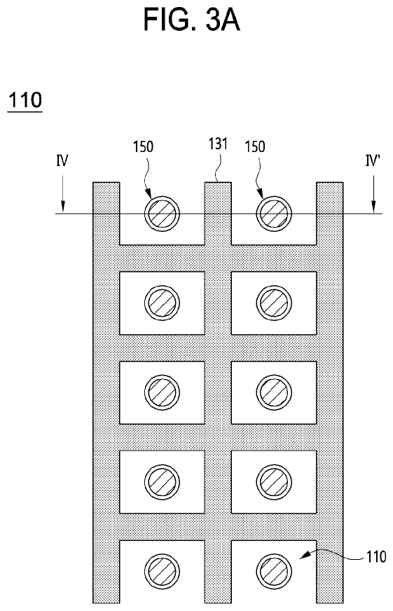

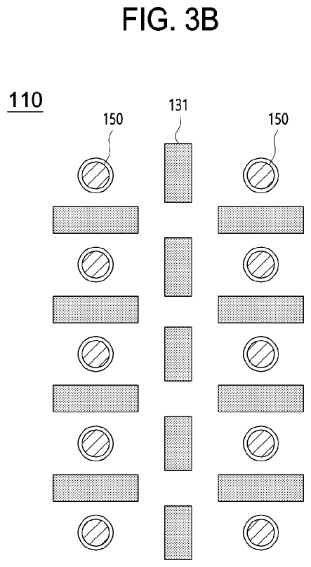

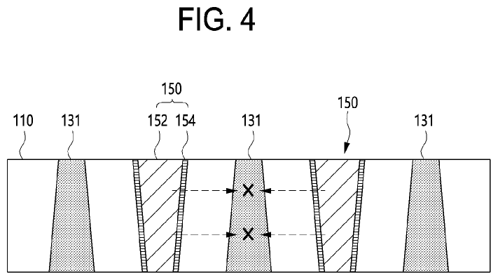

FIGS. 3A and 3B are plan views illustrating a polishing stop layer based on example embodiments and FIG. 4 is a cross-sectional view taken along a line IV-IV′ in FIG. 3A.

Referring to FIG. 3A, a polishing stop layer 131 based on example embodiments may be arranged between the adjacent conductive structures 150.

In example embodiments, as shown in FIG. 3A, the polishing stop layer 131 may have a grid shape configured to partition a plurality of conductive structures 150 into individual conductive structures 150.

Referring to FIG. 3B, a planar structure of the polishing stop layer 131 may have a dash shape or a dot shape between the conductive structures 150.

As the integration density or the level of integration of a semiconductor integrated circuit device increase, the density of the conductive structures 150 in the thin substrate 110 may also increase. In some implementations, the conductive via 152 corresponding to an actual conductive material of the conductive structure 150 is electrically isolated by the thin substrate 110 and the sidewall insulation layer 154, and thus when the conductive structures 150 may be densely distributed, signals generated by a conductive structure may be interfered by other signals generated by adjacent conductive structures 150, deteriorating electrical characteristics of the semiconductor integrated circuit device.

In example embodiments, the polishing stop layer 131 including the insulation material may be interposed between the densely or closely arranged conductive structures 150. Thus, the signal interference between the conductive structures 150 may be reduced by the polishing stop layer 131.

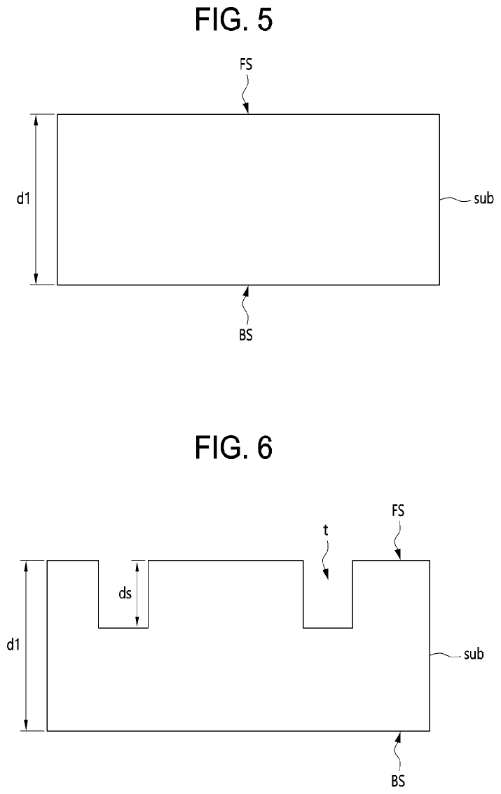

FIGS. 5 to 8 are cross-sectional views illustrating a method of manufacturing a thin wafer based on example embodiments.

In some implementations, a semiconductor substrate sub may include a bulk wafer or a bulk semiconductor substrate including a semiconductor material.

Referring to FIG. 5, the semiconductor substrate sub may have a first thickness d1. The semiconductor substrate sub may have a front surface FS and a bottom surface BS opposite to each other. The front surface FS and the bottom surface BS may be spaced apart from each other by the first thickness d1.

Referring to FIG. 6, at least one first trench t may be formed at a selected portion of the semiconductor substrate sub. The first trench t may have a depth ds from the front surface FS of the semiconductor substrate sub. The first depth ds may determine the first thickness d1 in FIG. 1. The first trench t may be formed to have a depth corresponding to an expected thickness of the thin substrate 110.

For example, the first depth ds may be less than the first thickness d1. In example embodiments, the first depth ds of the first trench t may be about 0.1% to about 2% of the first thickness d1. For example, when the first thickness d1 may be about 800 μm, the first depth ds may be about 0.8 μm to about 16 μm, particularly, about 5 μm to about 10 μm.

The selected portion(s) may be at least one of: a portion of the semiconductor substrate sub where the die 10 is to be formed; or a portion of the semiconductor substrate sub where the scribe lane SL is to be formed. For example, the first trench t includes a plurality of the first trenches t. The plurality first trenches t may be formed in the selected portions of the semiconductor substrate sub and the plan view and cross section view of the first trenches t may have various shapes. In some implementations, in the plan view, the first trenches t may be arranged symmetrically on the surface of the semiconductor substrate sub.

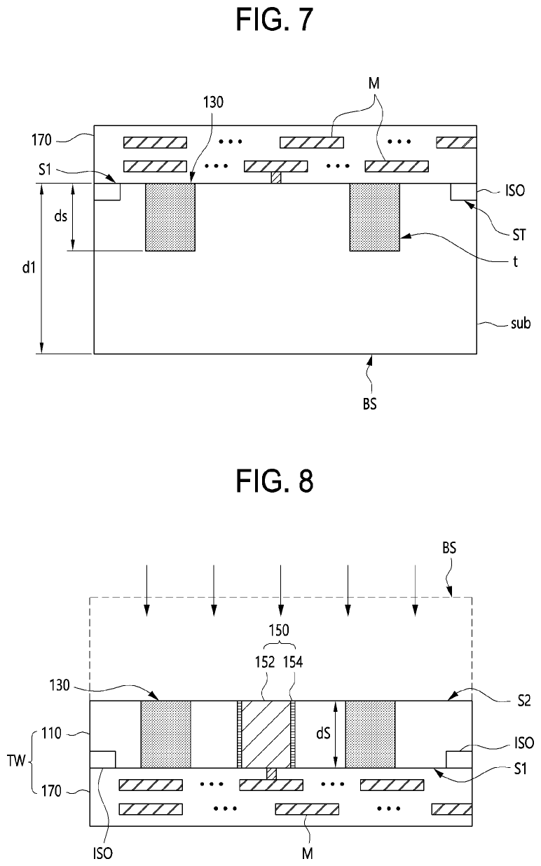

Referring to FIG. 7, the first trench t may be filled with an insulation material to form a polishing stop layer 130. For example, the insulation material may include at least one of silicon oxide, silicon nitride, or an organic insulating material, but the disclosed technology is not limited thereto.

Subsequently, an isolation layer ISO formation process and a well formation process may be performed on the semiconductor substrate sub.

The isolation layer ISO may have a shallow trench isolation (STI) structure. For example, a second trench ST may be formed in the semiconductor substrate sub. A depth of the second trench ST may be shallower than the first depth ds of the first trench t of the polishing stop layer 130. The second trench ST may be filled with an insulating material to form the isolation layer ISO.

In example embodiments, the process for filling the first trench t with the insulation material and the process for filling the second trench ST with the insulation material may be simultaneously performed. For example, the first trench t and the second trench ST may be formed at the semiconductor substrate sub. The first trench t and the second trench ST may be simultaneously filled with the insulation material to form the polishing stop layer 130 and the isolation layer ISO.

The device layer 170 may then be formed on the front surface FS of the semiconductor substrate sub. As mentioned above, the device layer 170 may include the active elements and/or the passive elements. As shown in FIG. 7, the multi interconnection layers M may be formed.

In example embodiments, the FEOL process and the BEOL process may be performed on the device layer 170.

Referring to FIG. 8, the bottom surface BS of the semiconductor substrate sub may be polished to form the thin substrate 110 having the first depth ds.

In some implementations, the semiconductor substrate sub may be placed so that the bottom surface BS of the semiconductor substrate sub faces toward an upper direction. The bottom surface BS of the semiconductor substrate sub may be polished until a bottom portion of the polishing stop layer 130 is exposed. Because the depth of the polishing stop layer 130 (e.g., the first depth ds) may be about 0.1% to about 2% of the first thickness d1 of the semiconductor substrate sub, the portion of the semiconductor substrate sub that is removed by polishing may be about 98% to about 99.9% of the first thickness t1 of the semiconductor substrate sub. For example, a chemical mechanical polishing (CMP) process may be performed on the semiconductor substrate sub, but the disclosed technology is not limited thereto.

For example, since the polishing stop layers 130 may be arranged symmetrically on the surface of the semiconductor substrate sub, the bottom surface BS of the semiconductor substrate sub may be polished (or removed) at a uniform polishing speed with respect to a whole bottom surface BS of the semiconductor substrate sub.

In example embodiments, when a specific portion of the semiconductor substrate sub are polished relatively quickly, the polishing stop layer(s) 130 may be densely arranged in the specific portion to control the polishing speed of the semiconductor substrate sub.

The thin substrate 110 may be formed by the above-mentioned processes. The first surface S1 of the thin substrate 110 may correspond to the front surface FS of the semiconductor substrate sub. The second surface S2 of the thin substrate 110 may be exposed.

The conductive structure 150 may be formed in the thin substrate 110. In example embodiments, a hole may be formed in the thin substrate 110. At least one of the interconnection layers M in the device layer 170 or conductive regions in the thin substrate 110 may be exposed through the hole. The sidewall insulation layer 154 may be formed on a sidewall of the hole. The hole may be filled with a conductive material to form the conductive via 152, to form the thin wafer TW. In example embodiments, the conductive structure 150 may be formed after polishing the semiconductor substrate sub. Alternatively, the conductive structure 150 may be formed before the polishing the semiconductor substrate sub, or in other processes.

Although not depicted in drawings, an external terminal such as a bonding pad may be formed on the conductive structure 150 exposed through the second surface S2.

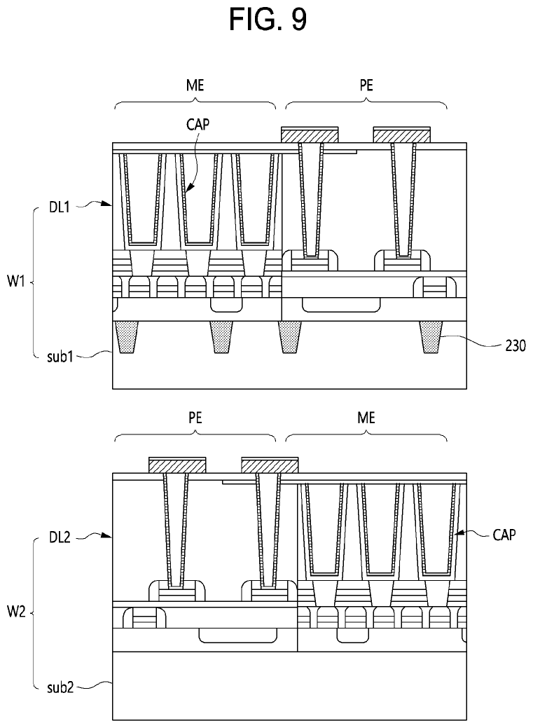

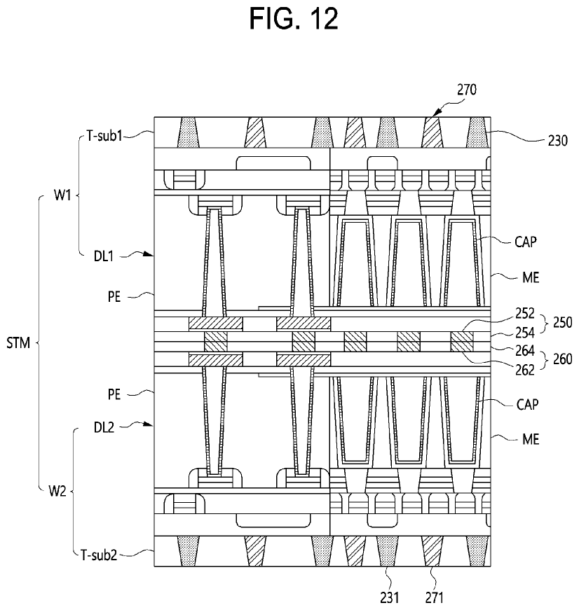

FIGS. 9 to 11 are cross-sectional views illustrating a method of manufacturing a stack type semiconductor device based on example embodiments and FIG. 12 is a cross-sectional view illustrating a stack type semiconductor device based on example embodiments.

Referring to FIG. 9, a first wafer W1 and a second wafer W2 may be prepared. The first wafer W1 and the second wafer W2 may include semiconductor substrates sub1 and sub2 and devices layers DL1 and DL2 on the semiconductor substrates sub1 and sub2, respectively.

The type and thickness of the first substrate sub1 of the first wafer W1 and the type and thickness of the second substrate sub2 of the second wafer W2 may be identical, but the disclosed technology is not limited thereto.

At least one of the first substrate sub1 or the second substrate sub2 may include a polishing stop layer 230. In example embodiments, the polishing stop layer 230 may be formed in the first substrate sub1. In some implementations, the polishing stop layer 230 may be formed in the first substrate sub1 and the second substrate sub2 in the same manner. In some implementations, the polishing stop layer 230 may be formed in a selected portion of the first substrate sub1 to have the insulation trench structure as illustrated in FIGS. 5 to 7. The polishing stop layer 230 may have a depth of about 0.1% to about 2% of the thickness of the first substrate sub1. The polishing stop layer 230 may have various widths and planar shapes changed based on an integration degree of the device layer DL1 of the first wafer W1 and a polishing speed obtained in a previous polishing process.

In an implementation, the first device layer DL1 of the first wafer W1 and the second device layer DL2 of the second wafer W2 may have substantially the same structure. In another implementation, the first device layer DL1 of the first wafer W1 and the second device layer DL2 of the second wafer W2 may have different structures.

For example, at least one of the first device layer DL1 or the second device layer DL2 may include a memory component ME and/or a logic/driver component PE. In example embodiments, all the first and second device layers DL1 and DL2 may include the memory component ME and the logic/driver component PE, but the disclosed technology is not limited thereto.

For example, the memory component ME may include a plurality of DRAM memory cells with a cell capacitor CAP. The logic/driver component PE may include circuits for performing memory operations of the DRAM memory cells.

In FIG. 9, the memory component ME and the logic/driver component PE may be horizontally arranged in parallel to each other, but the disclosed technology is not limited thereto. Alternatively, the memory component ME and the logic/drive component PE may be vertically stacked.

In example embodiments, the memory component ME may correspond to the pattern concentration region. The logic/driver component PE may include the dummy region.

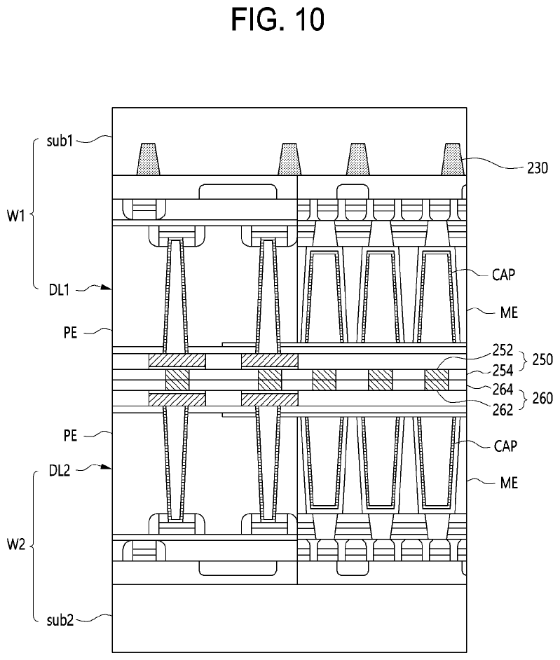

Referring to FIG. 10, a first bonding layer 250 may be formed on the first device layer DL1. A second bonding layer 260 may be formed on the second device layer DL2.

The first bonding layer 250 may include a plurality of first bonding pads 252 and a first bonding insulation layer 254. The first bonding pads 252 may be connected to electrodes in the first device layer DL1 or conductive patterns such as interconnection layers directly or indirectly connected to the electrodes. The first bonding insulation layer 254 may electrically isolate the first bonding pads 252 from each other.

The second bonding layer 260 may include a plurality of second bonding pads 262 and a second bonding insulation layer 264. The second bonding pads 262 may be connected to electrodes in the second device layer DL2 or conductive patterns such as interconnection layers or interconnects directly or indirectly connected to the electrodes. The second bonding insulation layer 264 may electrically isolate the second bonding pads 262 from each other.

The first wafer W1 may be placed such that the first bonding layer 250 of the first wafer W1 faces toward the second bonding layer 260 of the second wafer W2. The first wafer W1 may then be stacked on the second wafer W2.

In example embodiments, when the first wafer W1 may be stacked on the second wafer W2, the memory component ME of the first device layer DL1 may correspond to the memory component ME of the second device layer DL2 and the logic/driver component PE of the first device layer DL1 may correspond to the logic/driver component PE of the second device layer DL2. Thus, the first bonding layer 250 and the second bonding layer 260 may be in contact with each other. The bottom surface of the first wafer W1 may be upwardly exposed.

The first bonding layer 250 of the first wafer W1 and the second bonding layer 260 of the second wafer W2 may be hybrid-bonded to each other. Thus, the first wafer W1 may be stacked on the second wafer W2.

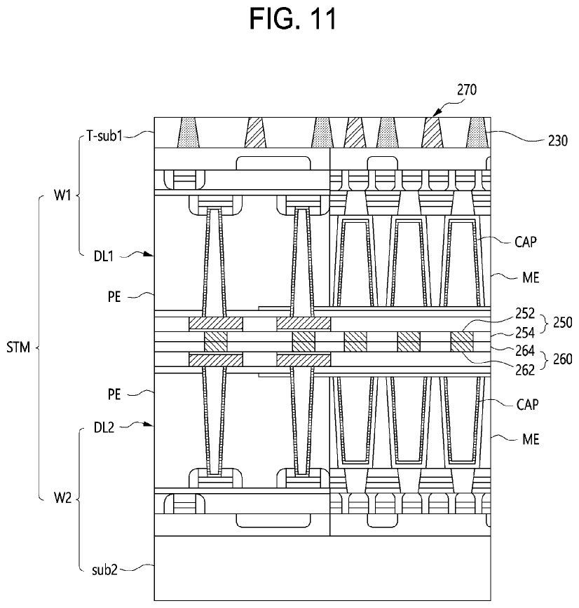

Referring to FIG. 11, the bottom surface of the first wafer W1 may be polished until the bottom surface of the polishing stop layer 230 may be exposed to form a thin substrate T-sub1.

A conductive structure 270 may be formed in the thin substrate T-sub. The conductive structure 270 may be formed in the tin substrate T-sub. The conductive structure 270 may be a vertical signal transmission wiring configured to transmitting an external signal to the electrodes of the first device layer DL1 or the interconnection layers connected to the electrodes after receiving the external signal. The conductive structure 270 may be formed by the above-mentioned processes based on example embodiments, or by a through silicon via (TSV) formation process.

In example embodiments, the conductive structure 270 may be positioned between the polishing stop layers 230. Because the polishing stop layer 230 including the insulation material may be placed between the densely arranged conductive structures 270, the signal interference between the adjacent conductive structures 270 may be reduced.

For example, any one of the conductive structures 270 electrically connected to a region corresponding to the memory component ME, e.g., the conductive patterns in the memory component ME may be relatively densely arranged. In order to reduce the signal interference between the densely arranged conductive structures 270, the conductive structures 270 may be positioned between the insulating polishing stop layers 230.

Alternatively, as shown in FIG. 12, the second substrate sub2 may also include a plurality of polishing stop layers 231 having an insulation trench shape. Thus, the second substrate sub2 may be polished using the polishing stop layers 231 to form a thin substrate T-sub2 for the second wafer W2.

For example, at least one conductive structure 251 in the pattern concentration region of the second device layer DL2, e.g., a region corresponding to the memory component ME of the second device layer DL2 may also be arranged between the polishing stop layers 231.

In example embodiments, the polishing stop layer having the insulation trench structure may be formed in the semiconductor substrate. In one example, the polishing stop layers may be arranged symmetrically on the surface of the semiconductor substrate. In another example, the polishing stop layer may be arranged in a region having a rapid polishing speed. In another example, the polishing stop layer may be arranged in a region having a low pattern density. In another example, the polishing stop layer may be arranged between adjacent conductive structures. Accordingly, the polishing uniformity of the semiconductor substrate may be improved. Therefore, the thin substrate, the thin wafer and the stack type semiconductor device may be manufactured without damage to the conductive members in the semiconductor substrate by improving the polishing uniformity.

While various embodiments of the disclosed technology have been described above, variations and enhancements of the disclosed embodiments and other embodiments may be made based on what is disclosed and/or illustrated in this patent document.

1. A wafer comprising:
a substrate including a first surface and a second surface opposite to each other;
a polishing stop layer formed in a selected portion of the substrate, the polishing stop layer including one or more insulation trenches each filled with an insulation material and having a depth corresponding to a thickness of the substrate; and
a device layer supported by the substrate and structured to include a plurality of conductive patterns configured to electrically connect different circuit elements in the substrate.

2. The wafer of claim 1, further comprising a plurality of conductive structures formed in the substrate and electrically connected to at least one of conductive patterns of the device layer.

3. The wafer of claim 2, wherein the polishing stop layer is positioned between adjacent conductive structures of the plurality of conductive structures.

4. The wafer of claim 2, wherein the polishing stop layer has a grid shape partition the plurality of conductive structures into individual conductive structures.

5. The wafer of claim 1, wherein the substrate comprises a plurality of die region and a scribe lane for defining the plurality of die regions, and the selected portion of the substrate includes at least one of the die regions or the scribe lane.

6. The wafer of claim 1, wherein the substrate comprises a pattern concentration region and a dummy region, and the selected portion of the substrate is at least one of the pattern concentration region or the dummy region, wherein a plurality of circuit patterns are distributed in the pattern concentration region and the dummy region, and a density of the plurality of circuit patterns in the pattern concentration region is higher than a predetermined density and a density of the plurality of circuit patterns in the dummy region is lower than the predetermined density.

7. The wafer of claim 1, further comprising an isolation layer formed in the substrate from the first surface of the substrate, the isolation layer having a depth shallower than a depth of the polishing stop layer.

8-20. (canceled)

21. A stack type semiconductor device comprising:
a first wafer including a first substrate and a first bonding layer disposed on the first substrate; and
a second wafer including a second substrate and a second bonding layer disposed on the second substrate to be attached to the first bonding layer using hybrid-bonding,
wherein the first substrate includes a plurality of first polishing stop layers, each of the first polishing stop layers includes one or more insulation trench structures that are filled with an insulation material and have a depth corresponding to a thickness of the first substrate.

22. The stack type semiconductor device of claim 21,
wherein the first bonding layer comprises a plurality of first bonding pads connected to interconnection layers of the first device layer and a first bonding insulation layer positioned between the first bonding pads, and
wherein the second bonding layer comprises a plurality of second bonding pads in contact with the first bonding pads and a second bonding insulation layer positioned between the second bonding pads.

23. The stack type semiconductor device of claim 21,
wherein the first wafer further comprises a first device layer including a plurality of first conductive patterns configured to electrically connect different circuit elements in the first wafer, and
wherein the second wafer further comprises a second device layer including a plurality of second conductive patterns configured to electrically connect different circuit elements in the second wafer.

24. The stack type semiconductor device of claim 23,
wherein the first substrate further comprises a plurality of first conductive structures formed in the first substrate and electrically connected to at least one of the first conductive patterns, and
wherein at least one of the first conductive structures is positioned between the first polishing stop layers.

25. The stack type semiconductor device of claim 24, wherein the first device layer comprises a pattern concentration region and a dummy region, and the first conductive structure between the first polishing stop layers is electrically connected to the first conductive pattern in the pattern concentration region, wherein a plurality of circuit patterns are distributed in the pattern concentration region and the dummy region, and a density of the plurality of circuit patterns in the pattern concentration region is higher than a predetermined density and a density of the plurality of circuit patterns in the dummy region is lower than the predetermined density.

26. The stack type semiconductor device of claim 23, wherein the second substrate comprises a plurality of second polishing stop layers and a plurality of second conductive structures, each of the second polishing stop layers has a depth corresponding to a thickness of the second substrate, and the second conductive structures are formed in the second substrate and electrically connected to at least one of the second conductive patterns.

27. The stack type semiconductor device of claim 26, wherein the second substrate comprises a pattern concentration region and a dummy region, and the second conductive structure between the second polishing stop layers is electrically connected to the second conductive pattern in the pattern concentration region of the second device layer.
